(19) United States
(12) Patent Application Publication
(10) Pub. No.: US 2019/0165722 A1
(43) Pub. Date: May 30, 2019

(54) Frame Compressing Device and Film Drawing Method

(71) Applicant: Beijing Chuangyu Technology Co., Ltd, Beijing (CN)

(72) Inventors: Jincheng ZOU, Beijing (CN); Min WEI, Beijing (CN); Bingbing SHEN, Beijing (CN)

(21) Appl. No.: 16/022,727

(22) Filed: Jun. 29, 2018

(30) Foreign Application Priority Data
Nov. 29, 2017 (CN) 201711230732.X

(51) Int. Cl. H02S 30/10; H02S 20/30; H02S 30/20

(52) U.S. Cl. CPC H02S 30/10; H02S 30/20; H02S 20/30

(57) ABSTRACT

The present disclosure relates to the technical field of solar cells, and more particularly to a frame compressing device and a film drawing method. The frame compressing device includes a fixing component and a driving component. The fixing component includes a first fixing block and a second fixing block. The first fixing block and the second fixing block are opposite to each other and are respectively configured to connect and fix two borders of a frame. The driving component is connected to the first fixing block and/or the second fixing block to drive the first fixing block and/or the second fixing block to move, so as to compress the frame. In the present disclosure, by using the characteristic that the frame has a certain elastic deformability, so as to solve the problems that a film is bonded to a frame in a loosened state and folds are formed.

### TECHNICAL FIELD

The present disclosure relates to the technical field of solar cells, and more particularly to a frame compressing device and a film drawing method.

### BACKGROUND

In a manufacturing process of solar cells, it is necessary to bond a film to a frame for transportation and subsequent processing. The frame is made of resin and has a certain strength and elasticity. Two adhesive tapes are bonded to two edges of the frame, and the middle is hollowed. At present, in the field, the frame is not accurately positioned before the film, is bonded to the frame, and is not compressed. The entire plane of the bonded film is in a loosened state, and more seriously, folds are formed, thereby affecting subsequent processing.

### SUMMARY

### (1) Technical Problem to be Solved

The technical problem to be solved by some embodiments of the present disclosure is a problem in the related art that folds are easily formed after a film is bonded to a frame and is in a loosened state.

### (2) Technical Solution

In order to solve the above technical problem, an embodiment provides a frame compressing device. The frame compressing device includes a fixing component and a driving component. The fixing component includes a first fixing block and a second fixing block. The first fixing block and the second fixing block are opposite to each other and are respectively configured to connect and fix two borders of a frame. The driving component is connected to the first fixing block and/or the second fixing block to drive the first fixing block and/or the second fixing block to move, so as to compress the frame.

In an exemplary embodiment, the device further includes a blocking component. The blocking component is disposed at a non-fixed position of the frame.

In an exemplary embodiment, the blocking component includes a blocking piece and a blocking piece driver. The blocking piece driver is connected to the blocking piece to control contact between the blocking piece and the frame.

In an exemplary embodiment, the driving component includes a driver and a guide rail. The guide rail is disposed along a compression direction of the frame. The first fixing block and/or the second fixing block are/is disposed on the guide rail. The driver is connected to the first fixing block and/or the second fixing block to drive the first fixing block and/or the second fixing block to move toward each other along the guide rail.

In an exemplary embodiment, the driver is a compressing cylinder, located between the first fixing block and the second fixing block.

In an exemplary embodiment, the device further includes a buffer. The buffer is disposed between the first fixing block and the second fixing block, which exerts a buffer force opposite to the compression direction of the frame on the first fixing block and/or the second fixing block.

In an exemplary embodiment, the device further includes a mounting plate. Both the driving component and the blocking piece driver are fixed to the mounting plate. The buffer is fixed to the mounting plate through a connecting member.

In an exemplary embodiment, the first fixing block and the second fixing block are provided with a vacuum suction hole separately, and suck the lower surfaces of the two borders of the frame respectively.

In an exemplary embodiment, the device further includes a vacuum generation device. The vacuum generation device fixes the frame to the first fixing block and the second fixing block through the vacuum suction holes.

In an exemplary embodiment, the first fixing block and the second fixing block are provided with two positioning columns separately, and the distance between the two positioning columns is a length of the border of the frame, fixed by the two positioning columns.

In an exemplary embodiment, the device further includes a control element. The control element includes a sensor and a controller. The sensor is configured to detect the compression degree of the frame and transmit a detection signal to the controller. The controller is connected to the driving component so as to control a movement distance of the first fixing block and/or the second fixing block under the drive of the driving component through the detection signal.

In an exemplary embodiment of the present disclosure also provides a film drawing method, which includes the following steps:

S1. Two borders of a frame are respectively fixed to a first fixing block and a second fixing block, opposite to each other.

S2. A driving component is started to drive the second fixing block and the first fixing block to move toward each other, or to drive the second fixing block to move near the first fixing block so as to bend the frame.

S3. A film is conveyed over the frame and bonded to the two fixed borders of the frame.

S4. The driving component is started to drive the second fixing block and the first fixing block to move oppositely, or to drive the second fixing block to move away from the first fixing bock until the frame restores to a horizontal state.

In an exemplary embodiment, between step S1 and step S2, the method further includes the following step:

S121. A blocking component is started to block the frame from protruding upward, so that the frame forms a recessed state in a compression process.

Between step S2 and step S3, the method further includes the following step:

S231. The blocking component is started to be away from the frame.

### (3) Beneficial Effect

The above technical solution of the present disclosure has the following advantages. The frame compressing device and the film bonding method are a platform and method for bonding a film and a frame. Before the film is bonded, the first fixing block and the second fixing block of the fixing component can position two borders with adhesive tapes of the frame, and the first fixing block and the second fixing block are driven by the driving component to jointly or separately move, so that the first fixing block and the second fixing block move near each other to compress two borders without adhesive tapes of the frame, and the film is bonded after the frame forms a certain recess. After bonding, the compression is relieved, and the frame will restore to an uncompressed plane state. The frame restores from the compressed state to the uncompressed state, and two edges of the film are drawn equivalently, so that the entire surface of the film is smooth without folds, and the film is in a tightened state. In some embodiments of the present disclosure, by using the characteristic that the frame has a certain elastic deformability, the frame is bent by an exerted force, and after the film is bonded, the film is drawn by means of the strength of the frame restoring to smoothness, so as to solve the problems in the related art that a film is bonded to a frame in a loosened state and folds are formed.

Besides the above-described technical problem to be solved by the present disclosure, the technical features of the technical solution and the advantages brought by these technical features of the technical solution, other technical features of the some embodiments and advantages brought by these technical features will be further illustrated with reference to the accompanying drawings.

### BRIEF DESCRIPTION OF THE DRAWINGS

FIG. 1 is a schematic structure diagram of a frame compressing device according to an embodiment of the present disclosure;

FIG. 2 is a schematic structure diagram of a frame compressing device according to an embodiment of the present disclosure during frame compression;

FIG. 3 is a top view of a frame compressing device according to an embodiment of the present disclosure during frame compression; and

FIG. 4 is a schematic diagram of a frame compressing device according to an embodiment of the present disclosure during film bonding after frame compression.

In the drawings, 1, fixing component; 2, driving component; 3, vacuum suction hole; 4, blocking component; 5, buffer; 6, mounting plate; 7, positioning column; 8, frame; 9, film; 11, first fixing block; 12, second fixing block; 21, driver; 22, guide rail; 41, blocking piece; 42, blocking piece driver; 61, connecting member; 81, adhesive tape.

### DETAILED DESCRIPTION OF THE EMBODIMENTS

In order to make the objectives, technical solutions and advantages of the embodiments of the present disclosure clearer, the technical solutions in the embodiments of the present disclosure will be clearly and completely described hereinbelow with the drawings in the embodiments of the present disclosure. Obviously, the described embodiments are only part of the embodiments of the present disclosure, not all of the embodiments. On the basis of the embodiments of the present disclosure, all other embodiments obtained on the premise of no creative work of a person of ordinary skill in the art fall within the scope of protection of the present disclosure.

In the descriptions of the present disclosure, unless otherwise specified and limited, it should be noted that terms “mounting”, “mutual connection” and “connection” should be generally understood. For example, the term may be fixed connection, or detachable connection or integrated connection, may be mechanical connection or electrical connection, may be direct connection, may be indirect connection through an intermediate, or may be internal communication between two elements. A person of ordinary skill in the art may understand specific meanings of the above terms in the present disclosure according to specific situations.

In addition, in the descriptions of the present disclosure, unless otherwise specified and limited, “multiple”, “multiple pieces” and “multiple groups” mean two or more, and “several”, “several pieces” and “several groups” mean one or more.

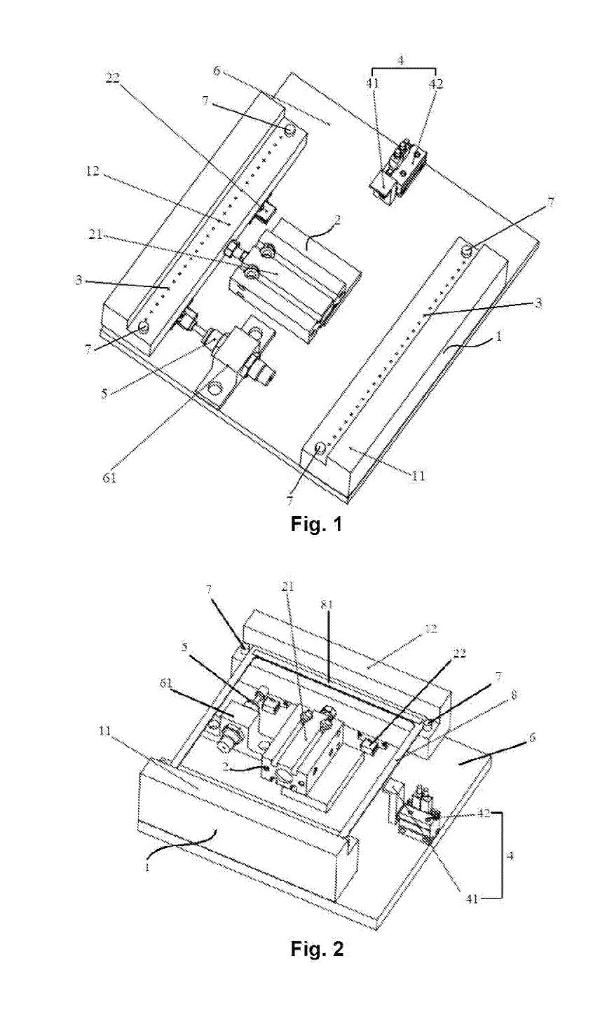

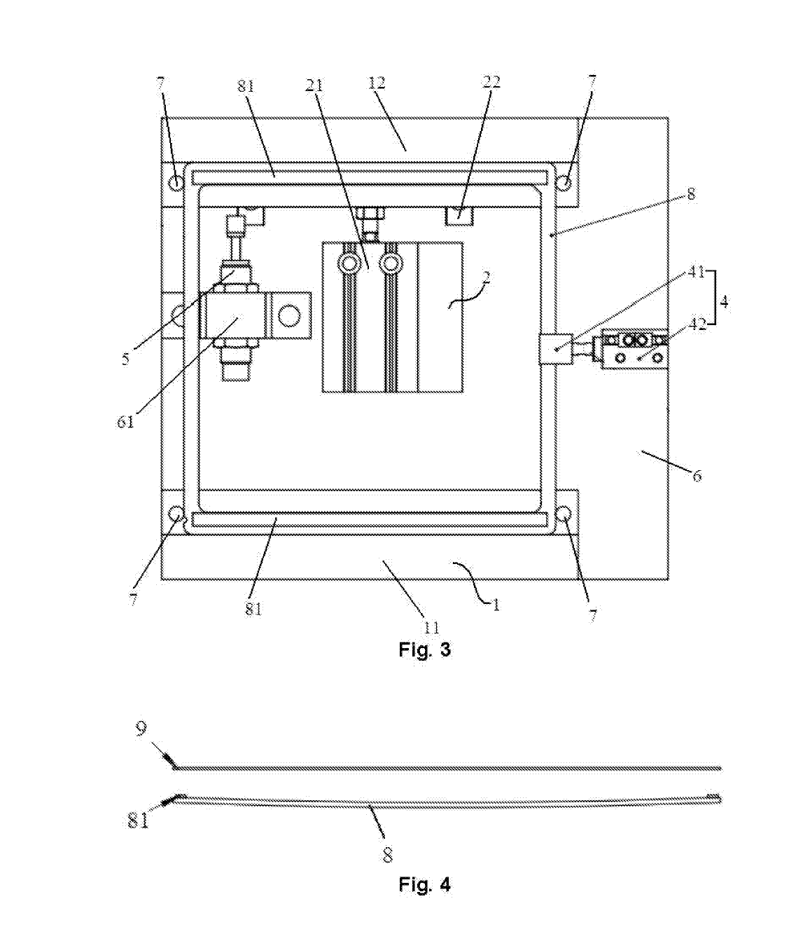

As shown in FIG. 1, FIG. 2, FIG. 3, and FIG. 4, a frame compressing device provided according to an embodiment of the present disclosure includes a fixing component 1 and a driving component 2. The fixing component 1 includes a first fixing block 11 and a second fixing block 12. The first fixing block 11 and the second fixing block 12 are opposite to each other and are respectively configured to connect and fix two borders of a frame 8. The driving component 2 is connected to the first fixing block 11 and/or the second fixing block 12 to drive the first fixing block 11 and/or the second fixing block 12 to move, so as to compress the frame.

The frame compressing device is a platform for bonding a film 9 and the frame 8. Before the film 9 is bonded, the first fixing block 11 and the second fixing block 12 of the fixing component 1 can position two borders with adhesive tapes 81 of the frame 8, and the first fixing block 11 and the second fixing block 12 are driven by the driving component 2 to simultaneously or separately move, so that the first fixing block 11 and the second fixing block 12 move near each other to compress two borders without adhesive tapes of the frame 8, and the film 9 is bonded after the frame 8 forms a certain recess. After bonding, the compression is relieved, and the frame 8 will restore to an uncompressed plane state. The frame 8 restores from the compressed state to the uncompressed state, and the film 9 is drawn equivalently, so that the entire surface of the film 9 is smooth without folds, and the film 9 is in a tightened state. In the present embodiment, by using the characteristic that the frame 8 has a certain elastic deformability, the frame 8 is bent by an exerted force, and after the film 9 is bonded, the film 9 is drawn by means of the strength of the frame 8 restoring to smoothness, so as to solve the problems in the related art that the film 9 is bonded to the frame 8 in a loosened state and folds are formed.

The frame compressing device of the present embodiment further includes a blocking component 4. The blocking component 4 is disposed at a non-fixed position of the frame 8. Specifically, after the frame 8 is fixed, the blocking component 4 is disposed at a border of the frame, not fixed by the fixing component 1, so as to exert a force on the frame 8 in a compression process, thereby preventing the frame 8 from protruding and bending toward a film to be fixed. The blocking component 4 may adopt a telescopic member, and may also adopt a flip buckle member. In the embodiment of the present disclosure, the blocking component may be disposed at a border, or may also be symmetrically disposed on two opposite borders, thereby avoiding the difference of the bending directions of the two borders. In the present embodiment, the blocking component 4 includes a blocking piece 41 and a blocking piece driver 42. A telescopic rod of the blocking piece driver 42 is connected to the blocking piece 41 to control contact between the blocking piece 41 and the frame 8. In the present embodiment, a telescopic member is adopted as the blocking component 4. The blocking component 4 is disposed on the periphery of one side of the non-fixed borders of the frame. The telescopic rod of the blocking piece driver 42 is connected to the blocking piece 41. When the telescopic rod of the blocking piece driver 42 stretchs out or draws back, the blocking piece 41 may be driven to move, and the blocking piece 41 can block the frame 8 from protruding upward during compression of the frame 8, thereby ensuring that the frame 8 forms a recessed state. In the present embodiment, the blocking piece driver 42 may adopt an element similar to a telescopic cylinder. When it is disposed on one side of the frame 8, a telescopic rod of the cylinder horizontally moves, the blocking piece 41 horizontally moves to the upper surface of the frame 8 and contacts it during extension, and the blocking piece 41 horizontally moves away from the upper surface of the frame 8 during retraction. It may also be disposed above the frame 8, the telescopic rod of the cylinder vertically moves, the blocking piece 41 vertically falls down to the upper surface of the frame 8 and contacts it during extension, and the blocking piece 41 vertically lifts away from the upper surface of the frame 8 during retraction.

Further, the driving component 2 includes a driver 21 and a guide rail 22. The guide rail 22 is disposed along a compression direction of the frame 8. The second fixing block 12 is disposed on the guide rail 22. The driver 21 is connected to the second fixing block 12 to drive the second fixing block 12 to move toward the first fixing block 11 along the guide rail. The bottom of the second fixing block 12 is connected to a sliding block through a bolt, and the sliding block is disposed on the guide rail 22 and linearly slides along the guide rail 22, so that the second fixing block 12 moves. The driver 21 may adopt a driving element similar to a cylinder or a screw nut to achieve linearly back and forth movement. In other embodiments of the present disclosure, guide rails 22 may also be mounted under the first fixing block 11 and the second fixing block 12. The driver 21 may simultaneously control the first fixing block 11 and the second fixing block 12 to push the first fixing block 11 and the second fixing block 12 to move toward from each other.

Herein, the driver 21 selected in the present embodiment is a compressing cylinder, located between the first fixing block 11 and the second fixing block 12, and connected to the second fixing block 12. In the present embodiment, before the frame 8 is placed, the telescopic rod of the driver 21 of the device is in an extension state, and the blocking piece driver 42 is in a retraction state.

The frame compressing device of the present embodiment further includes a buffer 5. The buffer 5 is disposed between the first fixing block 11 and the second fixing block 12, which exerts a buffer force opposite to the compression direction of the frame 8 on the second fixing block 12. The buffer 5 can achieve a buffer function when the first fixing block 11 and the second fixing block 12 move toward each other, thereby ensuring that the second fixing block 12 moves slowly and steadily, and avoiding the frame 8 from being broken and damaged due to over-load caused by instant drive of the driver 21. In other embodiments of the present disclosure, buffers 5 may also be mounted near the first fixing block 11 and the second fixing block 12 separately, and thereby the movement speed of the first fixing block 11 and the second fixing block 12 can be simultaneously controlled.

The frame compressing device of the present disclosure further includes a mounting plate 6. Both the driving component 2 and the blocking piece driver 42 are fixed to the mounting plate 6. The buffer 5 is fixed to the mounting plate 6 through a connecting member 61. The guide rail 22 is connected and fixed to the mounting plate 6 through a bolt, the driver 21 and the guide rail 22 are connected and fixed to the mounting plate 6 through bolts, the buffer 5 is sleeved by the connecting member 61, the connecting member 61 is connected and fixed to the mounting plate 6 through a bolt, the blocking piece driver 42 is connected and fixed to the mounting plate 6 through a bolt, and bolt connection facilitates disassembling.

Herein, the first fixing block 11 and the second fixing block 12 are provided with vacuum suction holes 3 separately, and suck the lower surfaces of the two borders of the frame 8 respectively. The frame 8 may be fixed to the first fixing block 11 and the second fixing block 12 in a manner such as bonding, pressing and sucking. In the present embodiment, since the surface, with an adhesive tape 81, of the frame 8 is upward, the film 9 can be directly conveyed over the frame 8 for bonding. The form of pressing is not convenient for bonding, so that the manner of sucking is selected. The first fixing block 11 and the second fixing block 12 have a certain number of vacuum suction holes 3 for providing a vacuum suction force in a vertical direction to suck the bottom surface of the borders by the adhesive tape 81 of the frame 8.

The frame compressing device of the present disclosure further includes a vacuum generation device. The vacuum generation device fixes the frame 8 to the first fixing block 11 and the second fixing block 12 through the vacuum suction holes 3. The vacuum suction forces generated by the first fixing block 11 and the second fixing block 12 are implemented by a vacuum generator.

Herein, the first fixing block 11 and the second fixing block 12 are provided with two positioning columns 7 separately, and the distance between the two positioning columns 7 is a length of the border of the frame, fixed by the two positioning columns 8. The first fixing block 11 and the second fixing block 12 are provided with two positioning columns 7 separately, so that two edges of the frame 8 can be positioned.

The frame compressing device of the present embodiment further includes a control element. The control element includes a sensor and a controller. The sensor is configured to detect the compression degree of the frame 8 and transmit a detection signal to the controller. The controller is connected to the driving component 2 so as to control a movement distance of the first fixing block 11 and/or the second fixing block 12 under the drive of the driving component 2 through the detection signal. The controller acquires compression information of the frame 8, detected by the sensor, so as to control the start/stop action of the driving component 2, thereby ensuring the consistency of the compression degree of the frame 8, and preventing the frame 8 from being broken and damaged due to over-compression.

The embodiment of the present disclosure also provides a film drawing method adopting the above frame compressing device, which includes the following steps:

S1. Two borders of a frame 8 are respectively fixed to a first fixing block 11 and a second fixing block 12, opposite to each other.

S2. A driving component 2 is started to drive the second fixing block 12 and the first fixing block 11 to move toward each other, or to drive the second fixing block 12 to move near the first fixing block 11 so as to bend the frame 8.

S3. A film 9 is conveyed over the frame 8 and bonded to the two fixed borders of the frame 8.

S4. The driving component 2 is started to drive the second fixing block 12 and the first fixing block 11 to move oppositely, or to drive the second fixing block 12 to move away from the first fixing bock 11 until the frame 8 restores to a horizontal state.

The film drawing method of the present embodiment is a method for drawing a film and a frame. Before the film 9 is bonded, two borders with the adhesive tapes 81 of the frame 8 are positioned by means of the first fixing block 11 and the second fixing block 12, and then the first fixing block 11 and the second fixing block 12 are driven by the driving component 2 to jointly or separately move, so that the first fixing block 11 and the second fixing block 12 move near each other to compress two borders without the adhesive tapes 81 of the frame 8, and the film 9 is bonded after the frame 8 forms a certain recess. After bonding, the compression is relieved, and the frame 8 will restore to an uncompressed plane state. The frame 8 restores from the compressed state to the uncompressed state, and two edges of the film 9 are drawn equivalently, so that the entire surface of the film 9 is smooth without folds, and the film 9 is in a tightened state. In the present embodiment, by using the characteristic that the frame 8 has a certain elastic deformability, the frame 8 is bent by an exerted force, and after the film 9 is bonded, the film 9 is drawn by means of the strength of the frame 8 restoring to smoothness, so as to solve the problems in the related art that the film 9 is bonded to the frame 8 in a loosened state and folds are formed.

Herein, in order to ensure that the frame 8 is deformed and bent downward in the compression process instead of protruding upward, between step S1 and step S2, the method further includes the following step:

S121. A blocking component 4 is started to block the frame 8 from protruding upward, so that the frame 8 forms a recessed state in a compression process.

In order to ensure that there is no barrier at the frame 8 before the film 9 is bonded after the frame 8 is recessed and bent, for convenience of bonding with the frame 8, between step S2 and step S3, the method further includes the following step:

S231. The blocking component 4 is started to be away from the frame 8.

To sum up, the frame compressing device and the film bonding method of the some embodiments of the present disclosure are a platform and method for bonding a film and a frame. Before the film is bonded, the first fixing block and the second fixing block of the fixing component can position two borders with adhesive tapes of the frame, and the first fixing block and the second fixing block are driven by the driving component to jointly or separately move, so that the first fixing block and the second fixing block move near each other to compress two borders without adhesive tapes of the frame, and the film is bonded after the frame forms a certain recess. After bonding, the compression is relieved, and the frame will restore to an uncompressed plane state. The frame restores from the compressed state to the uncompressed state, and two edges of the film are drawn equivalently, so that the entire surface of the film is smooth without folds, and the film is in a tightened state. In the some embodiments of the present disclosure, by using the characteristic that the frame has a certain elastic deformability, the frame is bent by an exerted force, and after the film is bonded, the film is drawn by means of the strength of the frame restoring to smoothness, so as to solve the problems in the related art that a film is bonded to a frame in a loosened state and folds are formed.

It shall be, finally, noted that: the above embodiments are merely intended to illustrate the technical solutions of the present disclosure and do not limit the technical solutions; although the some embodiments of the present disclosure is illustrated in detail with reference to the above embodiments, a person of ordinary skill in the art shall understand that they can still modify the technical solutions recorded by the above embodiments or can equivalently replace some of the technical features; and these modifications or replacements do not make the essences of corresponding technical solutions depart from the spirit and scope of the technical solutions in each embodiment of the present disclosure.

What is claimed is:

1. A frame compressing device, wherein the frame compressing device comprises a fixing component and a driving component, the fixing component comprises a first fixing block and a second fixing block, the first fixing block and the second fixing block are opposite to each other and are respectively configured to connect and fix two borders of a frame, and the driving component is connected to the first fixing block and/or the second fixing block to drive the first fixing block and/or the second fixing block to move, so as to compress the frame.

2. The frame compressing device as claimed in claim 1, wherein the frame compressing device further comprises a blocking component, and the blocking component is disposed at a non-fixed position of the frame.

3. The frame compressing device as claimed in claim 2, wherein the blocking component comprises a blocking piece and a blocking piece driver, and the blocking piece driver is connected to the blocking piece to control contact between the blocking piece and the frame.

4. The frame compressing device as claimed in claim 1, wherein the driving component comprises a driver and a guide rail, the guide rail is disposed along a compression direction of the frame, the first fixing block and/or the second fixing block are/is disposed on the guide rail, and the driver is connected to the first fixing block and/or the second fixing block to drive the first fixing block and/or the second fixing block to move toward each other along the guide rail.

5. The frame compressing device as claimed in claim 4, wherein the driver is a compressing cylinder.

6. The frame compressing device as claimed in claim 3, wherein the frame compressing device further comprises a buffer, which exerts a buffer force opposite to the compression direction of the frame on the first fixing block and/or the second fixing block.

7. The frame compressing device as claimed in claim 6, wherein the frame compressing device further comprises a mounting plate, both the driving component and the blocking piece driver are fixed to the mounting plate, and the buffer is fixed to the mounting plate through a connecting member.

8. The frame compressing device as claimed in claim 1, wherein the first fixing block and the second fixing block are provided with vacuum suction holes separately, and suck the lower surfaces of the two borders of the frame respectively.

9. The frame compressing device as claimed in claim 8, wherein the frame compressing device further comprises a vacuum generation device, and the vacuum generation device fixes the frame to the first fixing block and the second fixing block through the vacuum suction holes.

10. The frame compressing device as claimed in claim 1, wherein the first fixing block and the second fixing block are provided with two positioning columns separately, and thereby the distance between the two positioning columns is a length of the border of the frame, fixed by the two positioning columns.

11. The frame compressing device as claimed in claim 2, wherein the first fixing block and the second fixing block are provided with two positioning columns separately and thereby the distance between the two positioning columns is a length of the border of the frame, fixed by the two positioning columns.

12. The frame compressing device as claimed in claim 3, wherein the first fixing block and the second fixing block are provided with two positioning columns separately, and thereby the distance between the two positioning columns is a length of the border of the frame, fixed by the two positioning columns.

13. The frame compressing device as claimed in claim 4, wherein the first fixing block and the second fixing block are provided with two positioning columns separately, and thereby the distance between the two positioning columns is a length of the border of the frame, fixed by the two positioning columns.

14. The frame compressing device as claimed in claim 6, wherein the first fixing block and the second fixing block are provided with two positioning columns separately, and thereby the distance between the two positioning columns is a length of the border of the frame, fixed by the two positioning columns.

15. The frame compressing device as claimed in claim 7, wherein the first fixing block and the second fixing block are provided with two positioning columns separately, and thereby the distance between the two positioning columns is a length of the border of the frame, fixed by the two positioning columns.

16. The frame compressing device as claimed in claim 8, wherein the first fixing block and the second fixing block are provided with two positioning columns separately, and thereby the distance between the two positioning columns is a length of the border of the frame, fixed by the two positioning columns.

17. The frame compressing device as claimed in claim 9, wherein the first fixing block and the second fixing block are provided with two positioning columns separately and thereby the distance between the two positioning columns is a length of the border of the frame, fixed by the two positioning columns.

18. The frame compressing device as claimed in claim 9, wherein the frame compressing device further comprises a control element, the control element comprises a sensor and a controller, the sensor is configured to detect the compression degree of the frame and transmit a detection signal to the controller, and the controller is connected to the driving component so as to control a movement distance of the first fixing block and/or the second fixing block under the drive of the driving component through the detection signal.

19. A film drawing method, wherein the film drawing method comprises the following steps:
S1: respectively fixing two borders of a frame to a first fixing block and a second fixing block, opposite to each other;
S2: starting a driving component to drive the second fixing block and the first fixing block to move toward each other, or to drive the second fixing block to move near the first fixing block so as to bend the frame;
S3: conveying a film over the frame and bonding the film to the two fixed borders of the frame; and
S4: starting the driving component to drive the second fixing block and the first fixing block to move oppositely, or to drive the second fixing block to move away from the first fixing bock until the frame restores to a horizontal state.

20. The film drawing method as claimed in claim 19, wherein between step S1 and step S2, the method further comprises the following step:
S121: starting a blocking component to block the frame from protruding upward, so that the frame forms a recessed state in a compression process; and
between step S2 and step S3, the method further comprises the following step:
S231: starting the blocking component to make the blocking component away from the frame.
